(19) United States
(12) Patent Application Publication
(10) Pub. No.: US 2022/0189669 A1
(43) Pub. Date: Jun. 16, 2022

(54) ANISOTROPIC MAGNETIC POWDER, ANISOTROPIC MAGNET AND METHOD FOR MANUFACTURING ANISOTROPIC MAGNETIC POWDER

(71) Applicants: TDK CORPORATION, TOKYO (JP); NATIONAL INSTITUTE OF ADVANCED INDUSTRIAL SCIENCE AND TECHNOLOGY, TOKYO (JP)

(72) Inventors: Suguru SATOH, Tokyo (JP); Yasushi ENOKIDO, Tokyo (JP); Shusuke OKADA, Aichi (JP); Kenta TAKAGI, Aichi (JP)

(73) Assignees: TDK Corporation, Tokyo (JP); National Institute of Advanced Industrial Science and Technology, Tokyo (JP)

(21) Appl. No.: 17/593,090

(22) PCT Filed: Jan. 10, 2020
(86) PCT No.: PCT/JP2020/000734

§ 371 Date: Sep. 9, 2021

(30) Foreign Application Priority Data
Mar. 12, 2019 (JP) 2019-044954

(51) Int. Cl. H01F 1/059; H01F 41/02; C23C 8/26; C22C 1/04; C22C 28/00; C22C 32/00; C30B 29/52

(52) U.S. Cl. CPC H01F 1/059; H01F 41/02; C23C 8/26; C22C 2202/02; C22C 28/00; C22C 32/0089; C30B 29/52; C22C 1/04

(57) ABSTRACT

One embodiment of the present invention includes single-crystal particles of a TbCu₇ type samarium-iron-nitrogen based alloy in an anisotropic magnet powder.

### TECHNICAL FIELD

The present disclosure relates to an anisotropic magnetic powder, an anisotropic magnet and a method for manufacturing an anisotropic magnetic powder.

### BACKGROUND ART

In recent years, a TbCu₇ type samarium-iron-nitrogen magnet powder has been attracting attention as a raw material for a magnet having higher magnetic properties than those of a neodymium magnet.

The TbCu₇ type samarium-iron-nitrogen magnet powder is manufactured by nitriding a TbCu₇ type samarium-iron alloy powder. In addition, because the TbCu₇ type samarium-iron alloy is in a metastable phase, the TbCu₇ type samarium-iron alloy cannot be manufactured by a conventional alloying method by heat melting and cooling, and for example, the TbCu₇ type samarium-iron alloy is manufactured by an ultra-rapid quenching method (see Patent Documents 1 and 2).

### PRIOR ART DOCUMENTS

### Patent Documents

Patent Document 1: Japanese Patent Application Publication No. 7-118815

Patent Document 2: Japanese Patent Application Publication No. 5-279714

### SUMMARY OF THE INVENTION

### Problem to be Solved by the Invention

However, when using the ultra-rapid quenching method, only an isotropic magnet powder containing polycrystal particles of TbCu₇ type samarium-iron-nitrogen alloy with a random crystal orientation can be manufactured, and consequently, an anisotropic magnet with a high maximum energy product cannot be manufactured.

In order to manufacture an anisotropic magnet with a high maximum energy product, an anisotropic magnet powder containing single-crystal particles of a TbCu₇ type samarium-iron-nitrogen alloy needs to be manufactured.

One embodiment of the invention is intended to provide an anisotropic magnet powder containing single-crystal particles of a TbCu₇ type samarium-iron-nitrogen based alloy.

### Means for Solving the Problem

One embodiment of the present invention includes a single-crystal particle of a TbCu₇ type samarium-iron-nitrogen based alloy in an anisotropic magnet powder.

Another embodiment of the present invention includes a TbCu₇ type samarium-iron-nitrogen based alloy in an anisotropic magnet.

Another embodiment of the present invention includes, in a method for manufacturing an anisotropic magnet powder, steps of: producing a samarium-iron based alloy powder by heat treating a composition containing samarium, iron and an alkali metal halide and/or an alkaline earth metal halide at a temperature of a melting point of the alkali metal halide and/or the alkaline earth metal halide or higher; and producing a samarium-iron-nitrogen based alloy powder by nitriding the samarium-iron based alloy powder, wherein the temperature for heat treating is 500 degrees C. or higher and 800 degrees C. or less.

Another embodiment of the present invention includes, in a method for manufacturing a magnetic powder, steps of: producing a samarium-iron based alloy powder by heat treating a composition containing samarium, a samarium oxide and/or a samarium halide, iron, an iron oxide and/or an iron halide, an alkali metal halide and/or an alkaline earth metal halide, and an alkali metal and/or an alkaline earth metal at a temperature of a melting point of the alkali metal halide and/or the alkaline earth metal halide or higher; and producing a samarium-iron-nitrogen based alloy powder by nitriding the samarium-iron based alloy powder, wherein the temperature for heat treating is 500 degrees C. or higher and 800 degrees C. or less.

### ADVANTAGEOUS EFFECT OF THE INVENTION

According to an embodiment of the present invention, an anisotropic magnet powder containing single-crystal particles of a TbCu₇ type samarium-iron-nitrogen based alloy can be provided.

### BRIEF DESCRIPTION OF THE DRAWINGS

FIG. 1 shows an X-ray diffraction spectra of magnet powders of Examples 21, 24 and 25;

FIG. 2 shows a bright-field TEM image of a magnet powder of Example 21-6;

FIG. 3 shows a partially enlarged view of a bright-field TEM image in FIG. 2;

FIG. 4 shows a selected area diffraction image corresponding to a region C in FIG. 3; and

FIG. 5 shows an X-ray diffraction spectra of a sintered orientation plane and an amorphous orientation plane of sintered magnets of examples.

### EMBODIMENTS FOR CARRYING OUT THE INVENTION

Hereinafter, embodiments of the present invention will be described. The present invention is not limited to the contents described in the following embodiments. Also, the components described below include those that can be readily envisioned by a person skilled in the art and those that are substantially the same. In addition, the components described below may be properly combined with each other.

### Anisotropic Magnet Powder

An anisotropic magnet powder of the present embodiment contains single-crystal particles of a TbCu₇ type samarium-iron-nitrogen based alloy.

Here, the term “powder” refers to a mass of particles, and the term “single-crystal particle” refers to a solitary particle in which a particle without a crystal grain boundary and with a uniform crystal orientation does not agglutinate with other particles.

An intensity ratio of an X-ray diffraction peak of a (024) plane of a Th₂Zn₁₇ type samarium-iron-nitrogen based alloy phase to an X-ray diffraction peak of a (110) plane of a TbCu₇ type samarium-iron-nitrogen based alloy phase of an anisotropic magnet powder according to the present embodiment is preferably 0.300 or less, more preferably 0.100 or less, and further preferably 0.001 or less. When an intensity ratio of an X-ray diffraction peak of a (303) plane of the Th₂Zn₁₇ type samarium-iron-nitrogen based alloy phase to the X-ray diffraction peak of the (110) plane of the TbCu₇ type samarium-iron-nitrogen based alloy phase of the anisotropic magnetic powder according to the present embodiment is 0.300 or less, a proportion of the TbCu₇ type samarium-iron-nitrogen based alloy phase with respect to the anisotropic magnetic powder according to the present embodiment is sufficiently high.

A ratio c/a of a lattice constant c to a lattice constant a of the TbCu₇ type samarium-iron-nitrogen based alloy phase of the anisotropic magnet powder according to the present embodiment is preferably 0.838 or more, more preferably 0.840 or more, and even more preferably 0.845 or more. When the ratio c/a of the lattice constant c to the lattice constant a of the TbCu₇ type samarium-iron-nitrogen based alloy phase of the anisotropic magnetic powder according to the present embodiment is 0.838 or more, a proportion of Fe in the TbCu₇ type samarium-iron-nitrogen based alloy phase with respect to the anisotropic magnetic powder according to the present embodiment is sufficiently high. As a result, the magnetic properties of the anisotropic magnet powder in the present embodiment are improved.

An integral width of a (101) plane X-ray diffraction peak of the TbCu₇ type samarium-iron-nitrogen based alloy phase with respect to the anisotropic magnet powder according to the present embodiment is preferably 0.66 degrees or less, and further preferably 0.54 degrees or less. When the integral width of the (101) plane X-ray diffraction peak of the TbCu₇ type samarium-iron-nitrogen based alloy phase of the magnetic powder according to the present embodiment is 0.66 degrees or less, the crystallinity of the anisotropic magnetic powder according to the present embodiment is improved.

The coercivity of the anisotropic magnet powder according to the present embodiment is preferably 3.0 kOe or more, and further preferably 8.0 kOe or more.

The particle size of the anisotropic magnet powder according to the present embodiment is preferably 3 μm or less, and further preferably 1 μm or less. Because the particle size of single domain particles of the Th₂Zn₁₇ type samarium-iron-nitrogen based alloy is about 3 μm, and because an anisotropic magnetic field is about ⅓ of the Th₂Zn₁₇ type samarium-iron-nitrogen based alloy, the particle size of the single-domain particles of the TbCu₇ type samarium-iron-nitrogen based alloy is not considered to be beyond 3 μm.

Therefore, when the particle size of the anisotropic magnet powder according to the present embodiment is 3 μm or less, because a magnetic structure of the anisotropic magnet powder according to the present embodiment shifts from a multi-domain structure to a single-domain structure, magnetic properties of the anisotropic magnet powder according to the present embodiment increases. In addition, when the particle size of the anisotropic magnet powder according to the present embodiment is 1 μm or less, because the formation of the nucleation reversed domains can be inhibited, the magnetic properties of the anisotropic magnet powder according to the present embodiment further increase.

### First Method of Manufacturing Anisotropic Magnet Powder

A first method for manufacturing an anisotropic magnet powder according to the present embodiment includes steps of: producing a samarium-iron based alloy powder by heat treating a composition containing samarium, iron and an alkali metal halide and/or an alkaline earth metal halide at a temperature of a melting point of the alkali metal halide and/or the alkaline earth metal halide or higher; and producing a samarium-iron-nitrogen based alloy powder by nitriding the samarium-iron based alloy powder.

Here, the heat-treating temperature is 500 degrees C. or higher and 800 degrees C. or less, and is preferably 550 degrees C. or higher and 650 degrees C. or less. Therefore, it is possible to alloy at a temperature significantly lower than the melting point of the metal constituting the samarium-iron based alloy, and as a result, a samarium-iron based alloy powder containing single-crystal particles of the TbCu₇ type samarium-iron based alloy can be manufactured. In addition, by nitriding the samarium-iron based alloy powder, an anisotropic magnet powder containing single-crystal particles of the TbCu₇ type samarium-iron-nitrogen based alloy can be manufactured.

In the specification and claims, when the alkali metal halide and/or the alkaline earth metal halide is a mixture, the temperature of the melting point of the alkali metal halide and/or the alkaline earth metal halide or higher means a temperature of the eutectic point of the mixture or higher shown in a state diagram.

### Heat Treatment

Examples of the form of samarium include a powder and the like.

Examples of iron forms include a powder and the like. On this occasion, by using an iron powder having a particle size smaller than that of the single-domain particles of a TbCu₇ type samarium-iron-nitrogen based alloy, it is possible to manufacture a samarium-iron-based alloy powder containing single-crystal particles of a TbCu₇ type samarium-iron based alloy having a particle size smaller than that of the single domain particles of a TbCu₇ type samarium-iron-nitrogen based alloy. In addition, by nitriding the samarium-iron-based alloy powder, an anisotropic magnet powder containing single-crystal particles of a TbCu₇ type samarium-iron-nitrogen based alloy can be manufactured, and as a result, an anisotropic magnet powder with high crystallinity and excellent coercivity can be obtained.

Halides of alkali metal and/or halides of alkaline earth metal include, for example, a fluoride, a chloride, a bromide, an iodide, and the like.

Examples of alkali metal halides include LiCl, KCl, NaCl, and the like, and two or more kinds thereof may be used together.

Examples of the halides of the alkaline earth metal include CaCl₂, MgCl₂, BaCl₂, SrCl₂, and the like, and two or more kinds thereof may be used together.

Forms of alkali metal halides and/or alkaline earth metal halides include, for example, a powder and the like.

The concentration of samarium in the alkali metal halide and/or the alkaline earth metal halide at the heat treatment temperature is preferably 3.2 mol/L or more and 8.2 mol/L or less, and further preferably 5.2 mol/L or more and 6.2 mol/L or less. Thus, for example, the generation of heterophases such as Sm-rich crystal phases (e.g., SmFe₂ phase, SmFe₃ phase) can be reduced.

### Nitriding

A method for nitriding the samarium-iron based alloy powder includes, but is not limited to, a method for heat treating the samarium-iron based alloy powder in an atmosphere such as ammonia, a gas mixture of ammonia and hydrogen, nitrogen, a gas mixture of nitrogen and hydrogen, and the like, at a temperature of 300 to 500 degrees C.

The nitrogen content in single-crystal particles of the TbCu₇ type samarium-iron-nitrogen based alloy influences the magnetic properties of the anisotropic magnet powder in the present embodiment. The optimal single-crystal particle composition of the TbCu₇ type samarium-iron-nitrogen based alloy for increasing the coercivity of the anisotropic magnet powder in the present embodiment is Sm_{0.667}Fe_{5.667}N_{1.26}. Therefore, it it is important to control the nitrogen content in the single-crystal particles of the TbCu₇ type samarium-iron-nitrogen based alloy. When the samarium-iron based alloy powder is nitridated using ammonia, it is possible to nitride the samarium-iron based alloy powder in a short period of time. However, the nitrogen content in the single-crystal particles of the TbCu₇ type samarium-iron-nitrogen based alloy may be greater than Sm_{0.667}Fe_{5.667}N_{1.26}. In this case, excessive nitrogen can be discharged from the crystal lattice by heat treating the samarium-iron-nitrogen based alloy powder in hydrogen after nitriding the samarium-iron based alloy powder.

For example, the amount of nitrogen contained in the single-crystal particles of the TbCu₇ type samarium-iron-nitrogen based alloy is optimized by first nitriding the samarium-iron based alloy powder in an atmosphere of a mixture of ammonia and hydrogen streams at 350 degrees C. to 450 degrees C. for 10 minutes to 2 hours, subsequently transitioning the atmosphere to an atmosphere of a hydrogen stream at the same temperature, and heat treating the samarium-iron based alloy powder for 30 minutes to 2 hours. Hydrogen is then removed by transitioning the atmosphere to an atmosphere of an argon stream and heat treating the samarium-iron-nitrogen based alloy powder at the same temperature for 10 minutes to 1 hour.

### Second Method of Manufacturing Anisotropic Magnet Powder

A second method for manufacturing an anisotropic magnet powder according to the present embodiment includes steps of: producing a samarium-iron alloy powder by heat treating a composition containing samarium, samarium oxide and/or samarium halide, iron, iron oxide and/or iron halide, an alkali metal halide and/or an alkaline earth metal halide, and an alkali metal and/or alkaline earth metal at a temperature of a melting point of the alkali metal halide and/or alkaline earth metal halide or higher; and producing a samarium-iron-nitrogen based alloy powder by nitriding the samarium-iron-nitrogen based alloy powder.

Here, the temperature for heat treating is 500 degrees C. or higher and 800 degrees C. or less, and preferably 550 degrees C. or higher and 650 degrees C. or less. Therefore, it is possible to alloy the composition at a temperature significantly lower than the melting point of the metal constituting the samarium-iron based alloy, and as a result, a samarium-iron based alloy powder containing single-crystal particles of the TbCu₇ type samarium-iron based alloy can be manufactured. In addition, by nitriding the samarium-iron based alloy powder, an anisotropic magnet powder containing single-crystal particles of the TbCu₇ type samarium-iron-nitrogen based alloy can be manufactured.

In the specification and claims, when the alkali metal halide and/or the alkaline earth metal halide is a mixture, a temperature of a melting point of the alkali metal halide and/or the alkaline earth metal halide or higher means a temperature of an eutectic point of the mixture or higher shown in a state diagram.

### Heat Treatment

Forms of samarium, samarium oxide and/or samarium halide include, for example, a powder.

The second method for manufacturing the anisotropic magnet powder according to the present embodiment uses samarium, a samarium oxide and/or a samarium halide, and preferably uses samarium. Therefore, it is possible to inhibit a remaining iron phase that is not alloyed with samarium, and as a result, the coercivity of the anisotropic magnet powder can be improved.

Examples of iron oxides include FeO, Fe₃O₄, and Fe₂O₃ and the like.

Examples of iron halides include iron (II) fluoride, iron (III) fluoride, iron (II) chloride, iron (III) chloride, iron (II) bromide, iron (III) bromide, and iron (II) iodide and the like.

Forms of iron, an iron oxide and/or an iron halide include, for example, a powder. On this occasion, by using an iron powder having a particle size smaller than that of a single-domain particle of a TbCu₇ type samarium-iron-nitrogen based alloy, it is possible to manufacture a samarium-iron based alloy powder containing single-crystal particles of a TbCu₇ type samarium-iron alloy having a particle size smaller than that of the single-domain particles of the TbCu₇ type samarium-iron-nitrogen based alloy. In addition, by nitriding the samarium-iron-based alloy powder, an anisotropic magnet powder containing single-crystal particles of a TbCu₇ type samarium-iron-nitrogen based alloy can be manufactured, and as a result, an anisotropic magnet powder with high crystallinity and excellent coercivity can be obtained.

Alkali metal halides and/or alkaline earth metal halides include, for example, a fluoride, a chloride, a bromide, an iodide and the like.

Examples of alkali metal halides include LiCl, KCl, NaCl and the like.

Examples of alkaline earth metal halides include CaCl₂, MgCl₂, BaCl₂, SrCl₂ and the like.

Forms of alkali metal halides and/or alkaline earth metal halides include, for example, a powder and the like.

Examples of alkali metals include sodium, lithium and the like.

Examples of alkaline earth metals include calcium, magnesium and the like.

Forms of alkali metals and/or alkaline earth metals include, for example, a powder and the like.

In the second method for manufacturing an anisotropic magnet powder according to the present embodiment, an alkali metal and/or an alkaline earth metal is used. Thus, the alkali metal and/or alkaline earth metal can reduce a samarium oxide and/or a samarium halide, an iron oxide and/or an iron halide, or can reduce the oxidized surface of samarium and/or iron. As a result, the generation of a heterophase such as a Sm-rich crystal phase (e.g., SmFe₂ phase, SmFe₃ phase) can be inhibited.

The concentration of samarium in the alkali metal halide and/or the alkaline earth metal halide at the heat treatment temperature is preferably 3.2 mol/L or more and 8.2 mol/L or less, and further preferably 5.2 mol/L or more and 6.2 mol/L or less. Thus, for example, the generation of a heterophase such as a Sm-rich crystal phase (e.g., SmFe₂ phase, SmFe₃ phase) can be inhibited.

### Nitriding

A method for nitriding the samarium-iron-based alloy powder includes, but is not limited to, a method for heat treating the samarium-iron based alloy powder in an atmosphere of ammonia, a gas mixture of ammonia and hydrogen, nitrogen, a gas mixture of nitrogen and hydrogen and the like, at a temperature of 300 to 500 degrees C.

The nitrogen content in single-crystal particles of a TbCu₇ type samarium-iron-nitrogen based alloy influences the magnetic properties of the anisotropic magnet powder in the present embodiment. The optimal composition of single-crystal particles of the TbCu₇ type samarium-iron-nitrogen based alloy for increasing the coercivity of the anisotropic magnet powder in the present embodiment is Sm_{0.667}Fe_{5.667}N_{1.26}. Therefore, it is important to control the nitrogen content in the single-crystal particles of the TbCu₇ type samarium-iron-nitrogen based alloy. When the samarium-iron based alloy powder is nitridated using ammonia, it is possible to nitride the samarium-iron based alloy powder in a short period of time. However, the nitrogen content in the single-crystal particles of the TbCu₇ type samarium-iron-nitrogen based alloy may be greater than Sm_{0.667}Fe_{5.667}N_{1.26}. In this case, excessive nitrogen can be discharged from the crystal lattice by heat treating the samarium-iron-nitrogen based alloy powder in hydrogen after nitriding the samarium-iron based alloy powder.

For example, to begin with, the amount of nitrogen contained in the single-crystal particles of the TbCu₇ type samarium-iron-nitrogen based alloy is optimized by nitriding the samarium-iron based alloy powder in an atmosphere of a mixture of ammonia and hydrogen streams at 350 degrees C. to 450 degrees C. for 10 minutes to 2 hours, subsequently transitioning the atmosphere to an atmosphere of a hydrogen stream at the same temperature, and heat treating the samarium-iron-nitrogen based alloy powder for 30 minutes to 2 hours. The hydrogen is then removed by transitioning the atmosphere to an atmosphere of an argon stream, and heat treating the samarium-iron-nitrogen based alloy powder at the same temperature between 0 to 1 hour.

### Other Steps in Anisotropic Magnet Powder Manufacturing Process

(Washing with Water)

The samarium-iron-nitrogen based alloy powder is preferably washed in water to remove an alkali metal halide and/or an alkaline earth metal halide.

For example, water is added to the samarium-iron-nitrogen based alloy powder, stirred, and then decanted repeatedly.

(Dehydrogenation)

When washing the samarium-iron-nitrogen based alloy powder with water, hydrogen may enter a gap between crystal lattices of a samarium-iron-nitrogen based alloy powder. In this case, the samarium-iron-nitrogen based alloy powder may be dehydrogenated.

A method of dehydrogenating the samarium-iron-nitrogen based alloy powder includes, but is not limited to, a method for heat treating the samarium-iron-nitrogen based alloy powder in a vacuum or in an inert gas atmosphere.

For example, the samarium-iron-nitrogen based alloy powder is heat treated in a vacuum or in an argon stream at 150 degrees C. to 250 degrees C. for 1 to 3 hours.

(Vacuum Drying)

The washed samarium-iron-nitrogen based alloy powder is preferably dried in a vacuum to remove water.

Preferably, the temperature at which the washed samarium-iron-nitrogen based alloy powder is dried in a vacuum is from room temperature to 100 degrees C. Therefore, it is possible to inhibit the oxidation of the samarium-iron-nitrogen based alloy powder.

Further, the washed samarium-iron-nitrogen based alloy powder may be replaced with an organic solvent that has a high volatility such as alcohol and that can mix with water, and then may be dried in a vacuum.

### Milling

The samarium-iron-nitrogen based alloy powder may be milled.

A jet mill, dry and wet ball mills, a vibration mill, a medium agitation mill and the like may be used to mill the samarium-iron-nitrogen based alloy powder.

### Anisotropic Magnet

The anisotropic magnet of the present embodiment contains a TbCu₇ type samarium-iron-nitrogen based alloy, and can be manufactured using the anisotropic magnet powder of the present embodiment.

A degree of anisotropy of an anisotropic magnet according to the present embodiment is preferably 1.0% or more, more preferably 5.0% or more, and even more preferably 10.0% or more. When the anisotropic magnet according to the present embodiment has a degree of anisotropy of 1.0% or more, the magnetic properties of the anisotropic magnet according to the present embodiment are high.

A squareness ratio of the anisotropic magnet according to the embodiment is preferably 0.60 or more, and further preferably 0.67 or more. When the squareness ratio of the anisotropic magnet according to the present embodiment is 0.60 or more, the magnetic properties of the anisotropic magnet according to the present embodiment are high.

The anisotropic magnet of the present embodiment may be an anisotropic bonded magnet or an anisotropic sintered magnet, but is preferably an anisotropic sintered magnet in tams of magnetic properties.

### Anisotropic Sintered Magnet

An intensity ratio of a (002) plane X-ray diffraction peak to a (110) plane X-ray diffraction peak of the TbCu₇ type samarium-iron-nitrogen based alloy phase of a crystal orientation plane of the anisotropic sintered magnet according to the embodiment exceeds 2.115. Magnetic properties of the anisotropic sintered magnet in the present embodiment are enhanced when the intensity ratio of the (002) plane X-ray diffraction peak to the (110) plane X-ray diffraction peak of the TbCu₇ type samarium-iron-nitrogen based alloy phase exceeds 2.115, which is a value of an isotropic magnetic powder.

When the (002) plane X-ray diffraction peak overlaps the (200) and (111) plane X-ray diffraction peaks, the ratio of the sum of the (002) plane, (200) plane and (111) plane X-ray diffraction peaks to the (110) plane X-ray diffraction peak of the TbCu₇ type samarium-iron-nitrogen based alloy phase of the anisotropic sintered magnet of the present embodiment exceeds 5.656.

The intensity ratio of the (024) plane X-ray diffraction peak of the Th₂Zn₁₇ type samarium-iron-nitrogen based alloy phase to the (110) plane X-ray diffraction peak of the TbCu₇ type samarium-iron-nitrogen based alloy phase of the anisotropic sintered magnet according to the present embodiment is preferably 0.300 or less, and is further preferably 0.001 or less. When the intensity ratio of the (024) plane X-ray diffraction peak of the Th₂Zn₁₇ type samarium-iron-nitrogen based alloy phase to the (110) plane X-ray diffraction peak of the TbCu₇ type samarium-iron-nitrogen based alloy phase of the anisotropic sintered magnet according to the present embodiment is 0.300 or less, the proportion of the TbCu₇ type samarium-iron-nitrogen based alloy with respect to the anisotropic sintered magnet according to the present embodiment is sufficiently high.

The ratio c/a of the lattice constant c to the lattice constant a of the TbCu₇ type samarium-iron-nitrogen based alloy phase of the anisotropic magnet according to the present embodiment is preferably 0.838 or more, and is further preferably 0.842 or more. If the ratio c/a of the lattice constant c to the lattice constant a of the TbCu₇ type samarium-iron-nitrogen based alloy phase of the anisotropic magnet of the present embodiment is 0.838 or more, the proportion of Fe with respect to the TbCu₇ type samarium-iron-nitrogen based alloy phase of the anisotropic magnet of the present embodiment is sufficiently high. As a result, the magnetic properties of the anisotropic sintered magnet according to the present embodiment are improved.

The integral width of the (101) plane X-ray diffraction peak of the TbCu₇ type samarium-iron-nitrogen based alloy phase of the crystal orientation plane of the anisotropic sintered magnet according to the present embodiment is preferably 0.66 degrees or less, and is further preferably 0.54 degrees or less. When the integral width of the (101) plane X-ray diffraction peak of the TbCu₇ type samarium-iron-nitrogen based alloy phase of the anisotropic sintered magnet according to the present embodiment is 0.66 degrees or less, the crystallinity of the anisotropic sintered magnet according to the present embodiment is improved.

The coercivity of the anisotropic sintered magnet according to the present embodiment is preferably 3.0 kOe or more, and is further preferably 6.0 kOe or more.

The crystal grain size of the anisotropic sintered magnet according to the present embodiment is preferably 3 μm or less, and is further preferably 1 μm or less.

Here, because the particle size of the single-domain particles of the Th₂Zn₁₇ type samarium-iron-nitrogen based alloy is approximately 3 μm and because the anisotropic magnetic field is approximately ⅓ of the Th₂Zn₁₇ type samarium-iron-nitrogen based alloy, the particle size of the single-domain particles of the TbCu₇ type samarium-iron-nitrogen based alloy is not considered to be beyond 3 μm.

Therefore, when the crystal grain size of the anisotropic sintered magnet according to the present embodiment is 3 μm or less, the magnetic structure of the anisotropic sintered magnet according to the present embodiment shifts from a multi-domain structure to a single-domain structure, thereby increasing the magnetic properties of the anisotropic sintered magnet according to the present embodiment. In addition, when the crystal grain size of the anisotropic sintered magnet according to the present embodiment is 1 μm or less, because the formation of the nucleation reversed domains can be inhibited, the magnetic properties of the anisotropic sintered magnet according to the embodiment further increase.

### Examples

Hereinafter, examples of the present invention will be described, but the present invention is not limited to the following examples.

### Production of Iron Powder

The 101.8 g of iron nitrate and 14.9 g of calcium nitrate were dissolved in 819 mL of water, and 441 mL of 1 mol of a potassium hydroxide solution was added dropwise while being stirred, and thus a suspension of iron hydroxide was obtained. Then, the suspension was filtered, washed, and the iron powder was dried overnight at 120 degrees C. in air using a hot air drying oven, and the iron hydroxide powder was obtained. Next, the iron hydroxide powder was reduced in a hydrogen gas stream at 500 degrees C. for 6 hours, and thus an iron powder was obtained.

### Example 1

(Heat Treatment)

After 0.20 g of the iron powder, 0.29 g of a samarium chloride powder, 0.60 g of the lithium chloride powder having a melting point of 605 degrees C., and 0.07 g of a calcium powder were placed in an iron crucible, the iron crucible was heat treated at 650 degrees C. for 6 hours in an argon atmosphere, and thus a samarium-iron alloy powder was obtained. The concentration of samarium in lithium chloride at 650 degrees C. was 3.2 mol/L.

The concentration of samarium in lithium chloride is determined by the following equation.

[(mass of samarium powder)/(molar mass of samarium)]/[(mass of lithium chloride)/(density of lithium chloride)]

(Nitriding)

The samarium-iron based alloy powder was heated up to 200 degrees C. in a hydrogen stream, then was raised to 320 degrees C. in a 1:2 volume ratio of ammonia-hydrogen mixture and held for 1 hour, and thus a samarium-iron-nitrogen based alloy powder was obtained. Next, a nitrogen content of the samarium-iron-nitrogen based alloy powder was optimized by holding the temperature at 320 degrees C., heat treating the samarium-iron-nitrogen based alloy powder in a hydrogen stream for 1 hour, and then heat treating the samarium-iron-nitrogen based alloy powder in an argon stream for 1 hour.

(Washing with Water)

The samarium-iron-nitrogen based alloy powder was washed with pure water, thereby removing unreacted samarium chloride, lithium chloride, unreacted calcium, and calcium chloride.

(Vacuum Drying)

The samarium-iron-nitrogen based alloy powder washed with pure water was replaced with isopropanol, and then dried in a vacuum at room temperature.

(Dehydrogenation)

The samarium-iron-nitrogen based alloy powder dried in a vacuum was dehydrogenated in a vacuum at 200 degrees C. for 3 hours, and thus a magnet powder was obtained.

### Example 2

A magnetic powder was obtained in the same manner as Example 1, except that the additive amounts of the samarium chloride powder and the calcium powder in the heat treatment were changed to 0.59 g and 0.14 g, respectively. Here, the concentration of samarium in lithium chloride at 650 degrees C. was 5.4 mol/L.

### Example 3

A magnetic powder was obtained in the same manner as Example 1, except that the additive amounts of the samarium chloride powder and the calcium powder in the heat treatment were changed to 0.90 g and 0.21 g, respectively. The concentration of samarium in lithium chloride at 650 degrees C. was 7.2 mol/L.

### Example 4

A magnetic powder was obtained in the same manner as Example 1, except that the additive amounts of the samarium chloride powder and the calcium powder in the heat treatment were changed to 1.21 g and 0.28 g, respectively. Here, the concentration of samarium in lithium chloride at 650 degrees C. was 8.4 mol/L.

### Example 5

A magnet powder was obtained in the same manner as Example 1, except that the additive amounts of the samarium chloride powder, the lithium chloride powder, the iron powder, and the calcium powder in the heat treatment were changed to 1.40 g, 1.42 g, 0.49 g, and 0.65 g, respectively. Here, the concentration of samarium in lithium chloride at 650 degrees C. was 5.4 mol/L.

### Examples 6 to 8

A magnet powder was obtained in the same manner as Example 5, except that the additive amounts of the calcium powder in the heat treatment were changed to 1.31 g, 1.96 g, and 2,62 g, respectively. Here, the concentration of samarium in lithium chloride at 650 degrees C. was 5.4 mol/L.

### Example 9

A magnetic powder was obtained in the same manner as Example 1, except that the magnetic powder was heat treated as follows.

(Heat Treatment)

After 0.24 g of an iron powder, 0.80 g of a samarium chloride powder, 0.51 g of a lithium chloride powder having a melting point of 605 degrees C., 0.22 g of a potassium chloride powder having a melting point of 770 degrees C., and 0.31 g of a calcium powder were placed in an iron crucible, the iron crucible was heat treated at 650 degrees C. for 6 hours in an argon atmosphere, and thus a samarium-iron alloy powder was obtained. Here, the concentration of samarium in lithium chloride and potassium chloride at 650 degrees C. was 4.9 mol/L.

### Example 10

A magnetic powder was obtained in the same manner as Example 1, except that the magnetic powder was heat treated as follows.

(Heat Treatment)

After 0.24 g of an iron powder, 0.80 g of a samarium chloride powder, 0.54 g of a lithium chloride powder having a melting point of 605 degrees C., 0.22 g of a sodium chloride powder having a melting point of 801 degrees C., and 0.29 g of a calcium powder were placed in an iron crucible, the iron crucible was heat treated at 650 degrees C. for 6 hours in an argon atmosphere, and thus a samarium-iron alloy powder was obtained. Here, the concentration of samarium in lithium chloride and sodium chloride at 650 degrees C. was 5.2 mol/L.

### Example 11

A magnetic powder was obtained in the same manner as Example 1, except that the magnetic powder was heat treated as follows.

(Heat Treatment)

After 0.24 g of an iron powder, 0.80 g of a samarium chloride powder, 0.47 g of a lithium chloride powder having a melting point of 605 degrees C., 0.31 g of a calcium chloride powder having a melting point of 772 degrees C., and 0.27 g of a calcium powder were placed in an iron crucible, the iron crucible was heat treated at 650 degrees C. for 6 hours in an argon atmosphere, and thus a samarium-iron alloy powder was obtained. Here, the concentration of samarium in lithium chloride and calcium chloride at 650 degrees C. was 4.5 mol/L.

### Example 12

A magnetic powder was obtained in the same manner as Example 1, except that the magnetic powder was heat treated as follows.

(Heat Treatment)

After 0.24 g of an iron powder, 0.80 g of a samarium chloride powder, 0.50 g of a lithium chloride powder having a melting point of 605 degrees C., 0.28 g of a magnesium chloride powder having a melting point of 714 degrees C., and 0.29 g of a calcium powder were placed in an iron crucible, the iron crucible was heat treated at 650 degrees C. for 6 hours in an argon atmosphere, and thus a samarium-iron alloy powder was obtained. Here, the concentration of samarium in lithium chloride and magnesium chloride at 650 degrees C. was 4.8 mol/L.

### Example 13

A magnetic powder was obtained in the same manner as Example 1, except that the magnetic powder was heat treated as follows.

(Heat Treatment)

After 0.24 g of an iron powder, 0.80 g of a samarium chloride powder, 0.57 g of a lithium chloride powder having a melting point of 605 degrees C., 0.57 g of a barium chloride powder having a melting point of 962 degrees C., and 0.27 g of a calcium powder were placed in an iron crucible, the iron crucible was heat treated at 650 degrees C. for 6 hours in an argon atmosphere, and thus a samarium-iron alloy powder was obtained. Here, the concentration of samarium in lithium chloride and barium chloride at 650 degrees C. was 4.5 mol/L.

### Example 14

A magnetic powder was obtained in the same manner as Example 1, except that the magnetic powder was heat treated as follows.

(Heat Treatment)

After 0.24 g of an iron powder, 0.80 g of a samarium chloride powder, 0.44 g of a lithium chloride powder having a melting point of 605 degrees C., 0.58 g of a strontium chloride powder having a melting point of 874 degrees C., and 0.27 g of a calcium powder were placed in an iron crucible, the iron crucible was heat treated at 650 degrees C. for 6 hours in an argon atmosphere, and thus a samarium-iron alloy powder was obtained. The concentration of samarium in lithium chloride and strontium chloride at 650 degrees C. was 4.5 mol/L.

### Example 15

A magnetic powder was obtained in the same manner as Example 1, except that the magnetic powder was heat treated as follows.

(Heat Treatment)

After 0.24 g of an iron powder, 0.28 g of a samarium oxide powder, 1.04 g of a lithium chloride powder having a melting point of 605 degrees C., and 0.19 g of a calcium powder were placed in an iron crucible, the iron crucible was heat treated at 650 degrees C. for 6 hours in an argon atmosphere, and thus a samarium-iron alloy powder was obtained. The concentration of samarium in lithium chloride at 650 degrees C. was 3.2 mol/L.

### Example 16

A magnet powder was obtained in the same manner as Example 15, except that the additive amounts of the samarium oxide powder and the calcium powder in the heat treatment were changed to 0.47 g and 0.33 g, respectively. Here, the concentration of samarium in lithium chloride at 650 degrees C. was 5.4 mol/L.

### Example 17

A magnet powder was obtained in the same manner as Example 15, except that the additive amounts of the samarium oxide powder and the calcium powder in the heat treatment were changed to 0.63 g and 0.43 g, respectively. The concentration of samarium in lithium chloride at 650 degrees C. was 7.2 mol/L.

### Example 18

A magnet powder was obtained in the same manner as Example 15, except that the additive amounts of the samarium oxide powder and the calcium powder in the heat treatment were changed to 0.73 g and 0.50 g, respectively. Here, the concentration of samarium in lithium chloride at 650 degrees C. was 8.4 mol/L.

### Example 19

A magnetic powder was obtained in the same manner as Example 1, except that the magnetic powder was heat treated as follows.

(Heat Treatment)

After 0.24 g of an iron powder, 0.40 g of a samarium powder, and 1.04 g of a lithium chloride powder having a melting point of 605 degrees C. were placed in an iron crucible, and the iron crucible was heat treated at 650 degrees C. for 6 hours in an argon atmosphere, and thus a samarium-iron alloy powder was obtained. Here, the concentration of samarium in lithium chloride at 650 degrees C. was 5.4 mol/L.

### Example 20

A magnetic powder was obtained in the same manner as Example 1, except that the magnetic powder was heat treated as follows.

(Heat Treatment)

After 0.29 g of an iron powder, 0.24 g of a samarium powder, 1.04 g of a lithium chloride powder having a melting point of 605 degrees C., and 0.20 g of a calcium powder were placed in an iron crucible, and the iron crucible was heat treated at 650 degrees C. for 6 hours in an argon atmosphere, and thus a samarium-iron alloy powder was obtained. The concentration of samarium in lithium chloride at 650 degrees C. was 3.2 mol/L.

### Example 21

A magnetic powder was obtained in the same manner as Example 1, except that the magnetic powder was heat treated as follows.

(Heat Treatment)

After 0.24 g of an iron powder, 0.40 g of a samarium powder, 1.04 g of a lithium chloride powder having a melting point of 605 degrees C., and 0.20 g of a calcium powder were placed in an iron crucible, and the iron crucible was heat treated at 650 degrees C. for 6 hours in an argon atmosphere, and thus a samarium-iron alloy powder was obtained. Here, the concentration of samarium in lithium chloride at 650 degrees C. was 5.4 mol/L.

### Example 22

A magnetic powder was obtained in the same manner as Example 1, except that the magnetic powder was heat treated as follows.

(Heat Treatment)

After 0.20 g of an iron powder, 0.54 g of a samarium powder, 1.04 g of a lithium chloride powder having a melting point of 605 degrees C., and 0.20 g of a calcium powder were placed in an iron crucible, and the iron crucible was heat treated at 650 degrees C. for 6 hours in an argon atmosphere, and thus a samarium-iron alloy powder was obtained. The concentration of samarium in lithium chloride at 650 degrees C. was 7.2 mol/L.

### Example 23

A magnetic powder was obtained in the same manner as Example 1, except that the magnetic powder was heat treated as follows.

(Heat Treatment)

After 0.19 g of an iron powder, 0.63 g of a samarium powder, 1.04 g of a lithium chloride powder having a melting point of 605 degrees C., and 0.20 g of a calcium powder were placed in an iron crucible, the iron crucible was heat treated at 650 degrees C. for 6 hours in an argon atmosphere, and thus a samarium-iron alloy powder was obtained. Here, the concentration of samarium in lithium chloride at 650 degrees C. was 8.4 mol/L.

### Example 24

A magnetic powder was obtained in the same manner as Example 1, except that the magnetic powder was heat treated as follows.

(Heat Treatment)

After 0.24 g of an iron powder, 0.40 g of a samarium powder, 0.35 g of a lithium chloride powder having a melting point of 605 degrees C., 0.71 g of a calcium chloride powder having a melting point of 772 degrees C., and 0.20 g of a calcium powder were placed in an iron crucible, and the iron crucible was heat treated at 600 degrees C. in an argon atmosphere for 6 hours, and thus a samarium-iron alloy powder was obtained. Here, the concentration of samarium in lithium chloride and calcium chloride at 600 degrees C. was 5.4 mol/L.

### Example 25

In the heat treatment, a magnetic powder was obtained in the same manner as Example 24, except that the heat treatment time was changed to 48 hours. The concentration of samarium in lithium chloride at 600 degrees C. was 5.4 mol/L.

### Example 26

A magnetic powder was obtained in the same manner as Example 1, except that the magnetic powder was heat treated as follows.

(Heat Treatment)

After 0.24 g of an iron powder, 0.25 g of a samarium powder, 0.35 g of a lithium chloride powder having a melting point of 605 degrees C., and 0.71 g of a calcium chloride powder having a melting point of 772 degrees C. were placed in an iron crucible, and the iron crucible was heat treated at 600 degrees C. for 6 hours in an argon atmosphere, a samarium-iron alloy powder was obtained. Here, the concentration of samarium in lithium chloride and calcium chloride at 600 degrees C. was 3.2 mol/L.

### Example 27

A magnet powder was obtained in the same manner as Example 26, except that the additive amount of samarium powder in the heat treatment was changed to 0.30 g. Here, the concentration of samarium in lithium chloride and calcium chloride at 600 degrees C. was 4.0 mol/L.

### Example 28

A magnet powder was obtained in the same manner as Example 26, except that the additive amount of samarium powder in the heat treatment was changed to 0.35 g. Here, the concentration of samarium in lithium chloride and calcium chloride at 600 degrees C. was 4.7 mol/L.

### Example 29

A magnet powder was obtained in the same manner as Example 26, except that the additive amount of samarium powder in the heat treatment was changed to 0.40 g. Here, the concentration of samarium in lithium chloride and calcium chloride at 600 degrees C. was 5.4 mol/L.

### Example 30

A magnet powder was obtained in the same manner as Example 24, except that the additive amount of calcium powder in the heat treatment was changed to 0.10 g. Here, the concentration of samarium in lithium chloride and calcium chloride at 600 degrees C. was 5.4 mol/L.

### Example 31

A magnet powder was obtained in the same manner as Example 24, except that the additive amount of calcium powder in the heat treatment was changed to 0.40 g. Here, the concentration of samarium in lithium chloride and calcium chloride at 600 degrees C. was 5.4 mol/L.

### Example 32

A magnet powder was obtained in the same manner as Example 24, except that the additive amount of samarium powder in the heat treatment was changed to 0.25 g. Here, the concentration of samarium in lithium chloride and calcium chloride at 600 degrees C. was 3.2 mol/L.

### Example 33

A magnet powder was obtained in the same manner as Example 24, except that the additive amount of samarium powder in the heat treatment was changed to 0.30 g. Here, the concentration of samarium in lithium chloride and calcium chloride at 600 degrees C. was 4.0 mol/L.

### Example 34

A magnet powder was obtained in the same manner as Example 24, except that the additive amount of samarium powder in the heat treatment was changed to 0.35 g. Here, the concentration of samarium in lithium chloride and calcium chloride at 600 degrees C. was 4.7 mol/L.

### Comparative Example 1

Production of a magnetic powder was attempted in the same manner as Example 2, except that the additive amounts of samarium chloride powder and lithium chloride powder in the heat treatment were changed to 0 g and 0.59 g, respectively, but the magnet powder could not be produced.

### Comparative Example 2

In a heat treatment, production of a magnetic powder was attempted in the same manner as Example 16, except that a lithium chloride powder was not added, but the magnetic powder could not be produced.

### Comparative Example 3

In a heat treatment, production of a magnetic powder was attempted in the same manner as Example 16, except that a calcium powder was not added, but the magnet powder could not be produced.

### Comparative Example 4

In a heat treatment, production of a magnetic powder was attempted in the same manner as Example 21, except that a lithium chloride powder was not added, but the magnetic powder could not be produced.

Table 1 shows conditions for a heat treatment.

TABLE 1

| | Fe OR Fe | | Sm OR Sm | | ALKALI | | ALKALINE | |
|---|---|---|---|---|---|---|---|---|
| | COMPOUND | | COMPOUND | | METAL HALIDE | | EARTH HALIDE | |
| | | ADDITIVE | | ADDITIVE | | ADDITIVE | | ADDITIVE |
| | | AMOUNT | | AMOUNT | | AMOUNT | | AMOUNT |
| | TYPE | [g] | TYPE | [g] | TYPE | [g] | TYPE | [g] |
| EXAMPLE 1 | Fe | 0.20 | SmCl₃ | 0.29 | LiCl | 0.60 | — | — |
| EXAMPLE 2 | Fe | 0.20 | SmCl₃ | 0.59 | LiCl | 0.60 | — | — |
| EXAMPLE 3 | Fe | 0.20 | SmCl₃ | 0.90 | LiCl | 0.60 | — | — |
| EXAMPLE 4 | Fe | 0.20 | SmCl₃ | 1.21 | LiCl | 0.60 | — | — |
| EXAMPLE 5 | Fe | 0.49 | SmCl₃ | 1.40 | LiCl | 1.42 | — | — |
| EXAMPLE 6 | Fe | 0.49 | SmCl₃ | 1.40 | LiCl | 1.42 | — | — |
| EXAMPLE 7 | Fe | 0.49 | SmCl₃ | 1.40 | LiCl | 1.42 | — | — |
| EXAMPLE 8 | Fe | 0.49 | SmCl₃ | 1.40 | LiCl | 1.42 | — | — |
| EXAMPLE 9 | Fe | 0.24 | SmCl₃ | 0.80 | LiCl, KCl | 0.51, 0.22 | — | — |
| EXAMPLE 10 | Fe | 0.24 | SmCl₃ | 0.80 | LiCl, NaCl | 0.54, 0.22 | — | — |
| EXAMPLE 11 | Fe | 0.24 | SmCl₃ | 0.80 | LiCl | 0.47 | CaCl₂ | 0.31 |
| EXAMPLE 12 | Fe | 0.24 | SmCl₃ | 0.80 | LiCl | 0.50 | MgCl₂ | 0.28 |
| EXAMPLE 13 | Fe | 0.24 | SmCl₃ | 0.80 | LiCl | 0.57 | BaCl₂ | 0.57 |
| EXAMPLE 14 | Fe | 0.24 | SmCl₃ | 0.80 | LiCl | 0.44 | SrCl₂ | 0.58 |
| EXAMPLE 15 | Fe | 0.24 | Sm₂O₃ | 0.28 | LiCl | 1.04 | — | — |
| EXAMPLE 16 | Fe | 0.24 | Sm₂O₃ | 0.47 | LiCl | 1.04 | — | — |
| EXAMPLE 17 | Fe | 0.24 | Sm₂O₃ | 0.63 | LiCl | 1.04 | — | — |
| EXAMPLE 18 | Fe | 0.24 | Sm₂O₃ | 0.73 | LiCl | 1.04 | — | — |
| EXAMPLE 19 | Fe | 0.24 | Sm | 0.40 | LiCl | 1.04 | — | — |
| EXAMPLE 20 | Fe | 0.29 | Sm | 0.24 | LiCl | 1.04 | — | — |
| EXAMPLE 21 | Fe | 0.24 | Sm | 0.40 | LiCl | 1.04 | — | — |
| EXAMPLE 22 | Fe | 0.20 | Sm | 0.54 | LiCl | 1.04 | — | — |
| EXAMPLE 23 | Fe | 0.19 | Sm | 0.63 | LiCl | 1.04 | — | — |
| EXAMPLE 24 | Fe | 0.24 | Sm | 0.40 | LiCl | 0.35 | CaCl₂ | 0.71 |
| EXAMPLE 25 | Fe | 0.24 | Sm | 0.40 | LiCl | 0.35 | CaCl₂ | 0.71 |
| EXAMPLE 26 | Fe | 0.24 | Sm | 0.25 | LiCl | 0.35 | CaCl₂ | 0.71 |
| EXAMPLE 27 | Fe | 0.24 | Sm | 0.30 | LiCl | 0.35 | CaCl₂ | 0.71 |
| EXAMPLE 28 | Fe | 0.24 | Sm | 0.35 | LiCl | 0.35 | CaCl₂ | 0.71 |
| EXAMPLE 29 | Fe | 0.24 | Sm | 0.40 | LiCl | 0.35 | CaCl₂ | 0.71 |
| EXAMPLE 30 | Fe | 0.24 | Sm | 0.40 | LiCl | 0.35 | CaCl₂ | 0.71 |
| EXAMPLE 31 | Fe | 0.24 | Sm | 0.40 | LiCl | 0.35 | CaCl₂ | 0.71 |
| EXAMPLE 32 | Fe | 0.24 | Sm | 0.25 | LiCl | 0.35 | CaCl₂ | 0.71 |
| EXAMPLE 33 | Fe | 0.24 | Sm | 0.30 | LiCl | 0.35 | CaCl₂ | 0.71 |
| EXAMPLE 34 | Fe | 0.24 | Sm | 0.35 | LiCl | 0.35 | CaCl₂ | 0.71 |
| COMPARATIVE | Fe | 0.20 | SmCl₃ | 0.59 | — | — | — | — |
| EXAMPLE 1 | | | | | | | | |
| COMPARATIVE | Fe | 0.24 | Sm₂O₃ | 0.47 | — | — | — | — |
| EXAMPLE 2 | | | | | | | | |
| COMPARATIVE | Fe | 0.24 | Sm₂O₃ | 0.47 | LiCl | 1.04 | — | — |
| EXAMPLE 3 | | | | | | | | |
| COMPARATIVE | Fe | 0.24 | Sm | 0.40 | — | — | — | — |
| EXAMPLE 4 | | | | | | | | |

| | ALKALINE | | | | |
|---|---|---|---|---|---|
| | EARTH METAL | | | | |
| | | ADDITIVE | HEATING | HEATING | CONCENTRATION |
| | | AMOUNT | TEMPERATURE | TIME | OF Sm |
| | TYPE | [g] | [° C.] | [h] | [mol/L] |
| EXAMPLE 1 | Ca | 0.07 | 650 | 6 | 3.2 |
| EXAMPLE 2 | Ca | 0.14 | 650 | 6 | 5.4 |
| EXAMPLE 3 | Ca | 0.21 | 650 | 6 | 7.2 |
| EXAMPLE 4 | Ca | 0.28 | 650 | 6 | 8.4 |
| EXAMPLE 5 | Ca | 0.65 | 650 | 6 | 5.4 |
| EXAMPLE 6 | Ca | 1.31 | 650 | 6 | 5.4 |
| EXAMPLE 7 | Ca | 1.96 | 650 | 6 | 5.4 |
| EXAMPLE 8 | Ca | 2.62 | 650 | 6 | 5.4 |
| EXAMPLE 9 | Ca | 0.31 | 650 | 6 | 4.9 |
| EXAMPLE 10 | Ca | 0.29 | 650 | 6 | 5.2 |
| EXAMPLE 11 | Ca | 0.27 | 650 | 6 | 4.5 |
| EXAMPLE 12 | Ca | 0.29 | 650 | 6 | 4.8 |
| EXAMPLE 13 | Ca | 0.27 | 650 | 6 | 4.5 |
| EXAMPLE 14 | Ca | 0.27 | 650 | 6 | 4.5 |
| EXAMPLE 15 | Ca | 0.19 | 650 | 6 | 3.2 |
| EXAMPLE 16 | Ca | 0.33 | 650 | 6 | 5.4 |
| EXAMPLE 17 | Ca | 0.43 | 650 | 6 | 7.2 |
| EXAMPLE 18 | Ca | 0.50 | 650 | 6 | 8.4 |
| EXAMPLE 19 | — | — | 650 | 6 | 5.4 |
| EXAMPLE 20 | Ca | 0.20 | 650 | 6 | 3.2 |
| EXAMPLE 21 | Ca | 0.20 | 650 | 6 | 5.4 |
| EXAMPLE 22 | Ca | 0.20 | 650 | 6 | 7.2 |
| EXAMPLE 23 | Ca | 0.20 | 650 | 6 | 8.4 |
| EXAMPLE 24 | Ca | 0.20 | 600 | 6 | 5.4 |
| EXAMPLE 25 | Ca | 0.20 | 600 | 48 | 5.4 |
| EXAMPLE 26 | — | — | 600 | 6 | 3.2 |
| EXAMPLE 27 | — | — | 600 | 6 | 4.0 |
| EXAMPLE 28 | — | — | 600 | 6 | 4.7 |
| EXAMPLE 29 | — | — | 600 | 6 | 5.4 |
| EXAMPLE 30 | Ca | 0.10 | 600 | 6 | 5.4 |
| EXAMPLE 31 | Ca | 0.40 | 600 | 6 | 5.4 |
| EXAMPLE 32 | Ca | 0.20 | 600 | 6 | 3.2 |
| EXAMPLE 33 | Ca | 0.20 | 600 | 6 | 4.0 |
| EXAMPLE 34 | Ca | 0.20 | 600 | 6 | 4.7 |
| COMPARATIVE | Ca | 0.14 | 650 | 6 | — |
| EXAMPLE 1 | | | | | |
| COMPARATIVE | Ca | 0.33 | 650 | 6 | — |
| EXAMPLE 2 | | | | | |
| COMPARATIVE | — | — | 650 | 6 | — |
| EXAMPLE 3 | | | | | |
| COMPARATIVE | Ca | 0.20 | 650 | 6 | — |
| EXAMPLE 4 | | | | | |

Next, the presence or absence of single-crystal particles of the TbCu₇ type samarium-iron-nitrogen alloy, the intensity ratio of the (024) plane X-ray diffraction peak of the Th₂Zn₁₇ type samarium-iron-nitrogen alloy phase to the (110) plane X-ray diffraction peak of the TbCu₇ type samarium-iron-nitrogen alloy phase (hereinafter referred to as an “intensity ratio of an X-ray diffraction peak”), the ratio c/a of the lattice constant c to the lattice constant a of the TbCu₇ type samarium-iron-nitrogen alloy phase (hereinafter referred to as a “lattice constant ratio”), an integral width of a (101) plane X-ray diffraction peak of the TbCu₇ type samarium-iron-nitrogen alloy phase (hereinafter referred to as an “integral width of an X-ray diffraction peak”), and the coercivity were evaluated.

### Presence or Absence of Single-Crystal Particles of Tbcu₇ Type Samarium-Iron-Nitrogen Alloy

The magnet powder was embedded in resin, polished, and then processed into a focused ion beam (FIB), and thus a thin section was obtained. Then, a transmission electron microscope (TEM) was used to obtain a selected area diffraction image of the thin section, thereby evaluating the presence or absence of single-crystal particles of the TbCu₇ type samarium-iron-nitrogen alloy.

Specifically, the presence or absence of the single-crystal particles of the TbCu₇ type samarium-iron-nitrogen alloy was evaluated by checking whether the selected area diffraction image of the thin section is a spot-like diffraction image unique to the single-crystal particles and matches the spatial group P6/mmm, which is a feature of the crystal structure of the TbCu₇ type samarium-iron-nitrogen alloy.

### Integral Width of X-ray Diffraction Peak, Lattice Constant Ratio, X-Ray Diffraction Peak

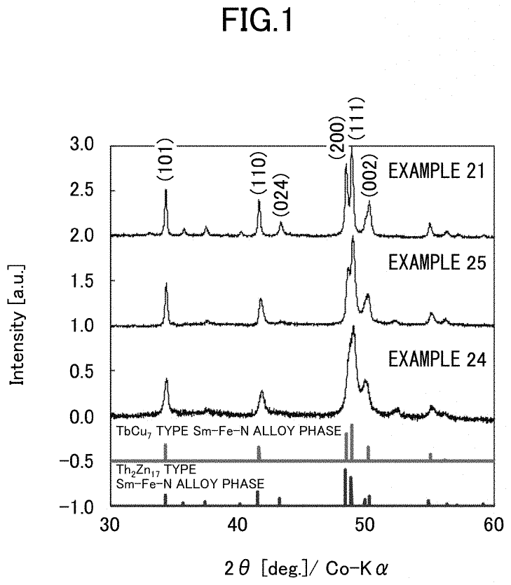

The X-ray diffraction spectra of the magnetic powder were measured using an X-ray diffraction device, Empyrean (made by Malvern Panalytical) and an X-ray detector, Pixcel 1D (made by Malvern Panalytical). Specifically, the X-ray diffraction spectrum of the magnet powder was measured using a Co-tube as an X-ray source under the conditions of a tube voltage of 45 kV, a tube current of 40 mA, a measurement angle of 30 to 60 degrees, a measurement step width of 0.013 degrees, and a width scan speed of 0.09 degrees/sec (see FIG. 1).

Peak searching and profile fitting were performed using High Score Plus (made by Malvern Panalytical) as the X-ray diffraction pattern analysis software, while setting the least significance difference at 1.00. Specifically, the integral intensity of the diffraction peak at the (110) plane of the TbCu₇ type samarium-iron-nitrogen alloy phase near 41.5 degrees and the integral intensity of the diffraction peak at the (024) plane of the Th₂Zn₁₇ type samarium-iron-nitrogen alloy phase near 43.2 degrees were obtained, and then the intensity ratio of the diffraction peak was calculated.

From FIG. 1, it can be seen that the ratio of the TbCu₇ type samarium-iron-nitrogen alloy phase is high because the magnet powders of Examples 21, 24, and 25 have intensity ratios of 0.289 <0.001, and 0.060, respectively.

After measuring the X-ray diffraction spectrum of the magnet powder (see FIG. 1), the lattice constant ratio was determined by performing Rietvelt analysis.

From FIG. 1, it was found that the lattice constant ratios for the magnet powders of Examples 21, 24, and 25 were 0.838, 0.845, and 0.842, respectively.

In addition, after measuring the X-ray diffraction spectrum of the magnet powder (see FIG. 1), the integral width of the (101) plane diffraction peak near 34.3 degrees was determined.

From FIG. 1, it was found that the integral widths of the X-ray diffraction peaks of the magnet powders of Examples 21, 24, and 25 were 0.33 degrees, 0.45 degrees, and 0.26 degrees, respectively.

### Coercivity

A magnet powder was mixed with thermoplastic resin and then oriented in a 20 kOe magnetic field, thereby producing a bonded magnet.

The bonded magnet was installed in the orientation direction using a vibration sample magnetometer VSM at a temperature of 27 degrees C. and in a maximum applied magnetic field of 90 kOe, and the coercivity was measured.

TABLE 2 shows evaluation results of the presence or absence of single-crystal particles of a TbCu₇ type samarium-iron-nitrogen alloy, an intensity ratio of an X-ray diffraction peak, a lattice constant ratio, an integral width of the X-ray diffraction peak, and coercivity.

TABLE 2

| | PRESENCE OR | INTENSITY | | INTEGRAL | |
|---|---|---|---|---|---|
| | ABSENCE OF SINGLE | RATIO OF | | WIDTH OF | |
| | CRYSTAL PARTICLE | X-RAY | LATTICE | X-RAY | |
| | OF TbCu₇ TYPE | DIFFRACTION | CONSTANT | DIFFRACTION | COERCIVITY |
| | Sm—Fe—N ALLOY | PEAK | RATIO | PEAK [°] | [kOe] |
| EXAMPLE 1 | PRESENCE | 0.291 | 0.838 | 0.32 | 5.6 |
| EXAMPLE 2 | PRESENCE | 0.293 | 0.838 | 0.35 | 6.8 |
| EXAMPLE 3 | PRESENCE | 0.270 | 0.838 | 0.32 | 5.9 |
| EXAMPLE 4 | PRESENCE | 0.276 | 0.838 | 0.36 | 3.3 |
| EXAMPLE 5 | PRESENCE | 0.290 | 0.838 | 0.44 | 6.8 |
| EXAMPLE 6 | PRESENCE | 0.267 | 0.838 | 0.32 | 5.4 |
| EXAMPLE 7 | PRESENCE | 0.264 | 0.838 | 0.36 | 4.6 |
| EXAMPLE 8 | PRESENCE | 0.291 | 0.838 | 0.34 | 3.7 |
| EXAMPLE 9 | PRESENCE | 0.278 | 0.838 | 0.32 | 5.0 |
| EXAMPLE 10 | PRESENCE | 0.282 | 0.838 | 0.35 | 6.8 |
| EXAMPLE 11 | PRESENCE | 0.283 | 0.838 | 0.36 | 6.8 |
| EXAMPLE 12 | PRESENCE | 0.265 | 0.838 | 0.34 | 5.2 |
| EXAMPLE 13 | PRESENCE | 0.277 | 0.838 | 0.34 | 6.4 |
| EXAMPLE 14 | PRESENCE | 0.273 | 0.838 | 0.33 | 6.5 |
| EXAMPLE 15 | PRESENCE | 0.281 | 0.838 | 0.32 | 5.2 |
| EXAMPLE 16 | PRESENCE | 0.265 | 0.838 | 0.36 | 6.6 |
| EXAMPLE 17 | PRESENCE | 0.272 | 0.838 | 0.35 | 5.7 |
| EXAMPLE 18 | PRESENCE | 0.280 | 0.838 | 0.35 | 3.1 |
| EXAMPLE 19 | PRESENCE | 0.276 | 0.838 | 0.44 | 7.6 |
| EXAMPLE 20 | PRESENCE | 0.271 | 0.838 | 0.32 | 7.6 |
| EXAMPLE 21 | PRESENCE | 0.289 | 0.838 | 0.33 | 7.6 |
| EXAMPLE 22 | PRESENCE | 0.277 | 0.838 | 0.36 | 7.6 |
| EXAMPLE 23 | PRESENCE | 0.282 | 0.838 | 0.34 | 3.3 |
| EXAMPLE 24 | PRESENCE | <0.001 | 0.845 | 0.45 | 7.2 |
| EXAMPLE 25 | PRESENCE | 0.060 | 0.842 | 0.26 | 7.5 |
| EXAMPLE 26 | PRESENCE | <0.001 | 0.845 | 0.48 | 1.9 |
| EXAMPLE 27 | PRESENCE | <0.001 | 0.845 | 0.34 | 3.1 |
| EXAMPLE 28 | PRESENCE | <0.001 | 0.845 | 0.45 | 4.2 |
| EXAMPLE 29 | PRESENCE | <0.001 | 0.845 | 0.56 | 5.9 |
| EXAMPLE 30 | PRESENCE | <0.001 | 0.845 | 0.46 | 7.8 |
| EXAMPLE 31 | PRESENCE | <0.001 | 0.845 | 0.49 | 5.1 |
| EXAMPLE 32 | PRESENCE | <0.001 | 0.845 | 0.45 | 3.2 |
| EXAMPLE 33 | PRESENCE | <0.001 | 0.845 | 0.29 | 4.3 |
| EXAMPLE 34 | PRESENCE | <0.001 | 0.845 | 0.34 | 5.3 |
| COMPARATIVE EXAMPLE 1 | ABSENCE | — | — | — | — |
| COMPARATIVE EXAMPLE 2 | ABSENCE | — | — | — | — |
| COMPARATIVE EXAMPLE 3 | ABSENCE | — | — | — | — |
| COMPARATIVE EXAMPLE 4 | ABSENCE | — | — | — | — |

From Table 2, it can be seen that the magnet powders of Examples 1 to 34 are anisotropic magnet powders containing single-crystal particles of a TbCu₇ type samarium-iron-nitrogen alloy.

In contrast, in Comparative Examples 1, 2, and 4, the samarium-iron alloy powder is not produced and the magnet powder cannot be produced because the heat treatment is performed at a temperature below the melting point of calcium.

In Comparative Example 3, because alkali metal or alkaline earth metal is not used, samarium oxide is not reduced, and a magnet powder cannot be produced.

### Example 21-1

A magnet powder was obtained in the same manner as Example 21 except that the temperature was raised to 270 degrees C. during nitriding.

### Example 21-2

A magnet powder was obtained in the same manner as Example 21 except that the temperature was raised to 370 degrees C. during nitriding.

### Example 21-3

A magnet powder was obtained in the same manner as Example 21 except that the temperature was raised to 420 degrees C. during nitriding.

### Examples 21-4

A magnet powder was obtained in the same manner as Example 21 except that the dehydrogenated samarium-iron-nitrogen alloy powder was milled as follows.

(Milling)

One gram of dehydrogenated samarium-iron-nitrogen alloy powder, 20 ml hexane, 100 g of a 0.5 mm diameter zirconia ball was put in a 100 ml plastic container, and then milled at 20 Hz for 1 hour using a vibrating mill apparatus, and thus a magnet powder was obtained.

### Examples 21-5

A magnetic powder was obtained in the same manner as that in Examples 21-4 except that a zirconia ball having a diameter of 1.0 mm was used in the milling process.

### Examples 21-6

A magnetic powder was obtained in the same manner as in Examples 21-4 except that a zirconia ball having a diameter of 1.5 mm was used in the milling process.

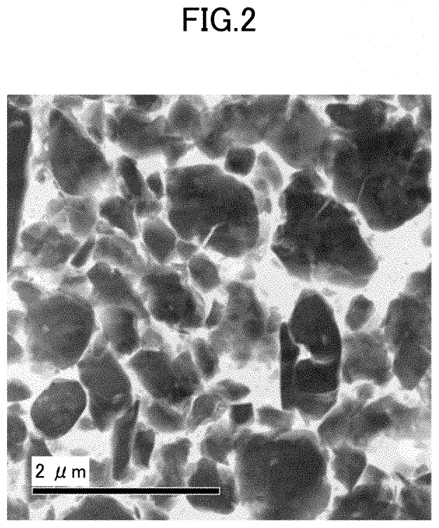

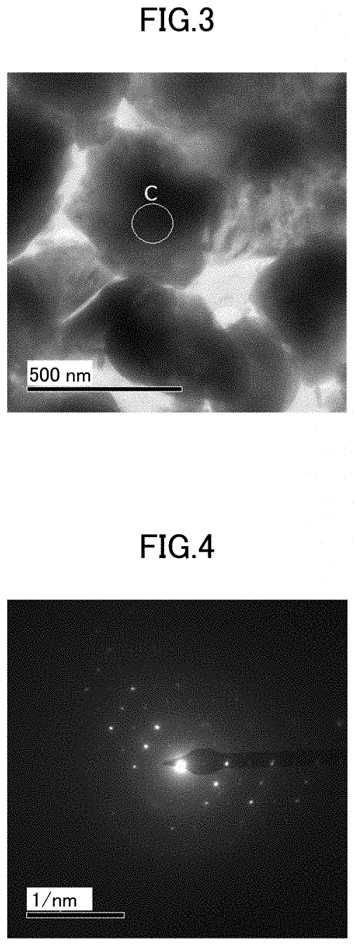

FIG. 2 shows a bright-field TEM image of the magnet powder of Examples 21-6. FIG. 3 is a partially enlarged view of the bright-field TEM image of FIG. 2, and FIG. 4 is a selected area diffraction image corresponding to the region C of FIG. 3.

From FIG. 2, it is found that the magnetic powder of Examples 21-6 has a particle size of 0.5 μm or more and 3.0 μm or less.

In addition, because the selected area diffraction image in FIG. 4 has spot-like shapes, it can be seen that the magnet powder in FIG. 2 contains single-crystal particles. Furthermore, because the selected area diffraction image of FIG. 4 is consistent with the spatial group P6/mm, which is a feature of the crystal structure of the TbCu₇ type samarium-iron-nitrogen alloy, it can be seen that the magnet powder contains single-crystal particles of the TbCu₇ type samarium-iron-nitrogen alloy.

### Examples 21-7

A magnetic powder was obtained in the same manner as Example 21-6, except that the milling time was changed to 3 hours.

### Examples 21-8

A magnetic powder was obtained in the same manner as Example 21-6, except that the milling time was changed to 5 hours.

### Comparative Examples 21-1

Samarium-iron alloy powder was obtained in the same manner as Example 21 except that the samarium-iron alloy powder was not nitrided.

### Comparative Example 5

The iron and samarium were weighed so that the iron content in the samarium-iron alloy was 90 at % and the samarium content in the samarium-iron alloy was 10 at %, and the samarium-iron alloy was obtained by arc dissolution method.

A samarium-iron alloy was melted by filling a quartz tube with a nozzle with the samarium-iron alloy and melting the samarium-iron alloy at high frequency. Next, Ar gas was blown from the upper portion of the quartz tube, and melted water of the samarium-iron alloy was injected from the nozzle to a rotating copper cooling roller, and a quench thin zone of the samarium-iron alloy was obtained. On this occasion, the circumferential speed of the cooling roll was set to 30 m/sec. The obtained quench thin zone was heated to 700 degrees C. for 30 minutes in an Ar atmosphere, and thus a samarium-iron alloy powder was obtained.

The magnet powder was obtained in the same manner as Example 21-3, except that the obtained samarium-iron alloy powder was used.

### Comparative Example 5-1

A magnet powder was obtained in the same manner as Comparative Example 5, except that the dehydrogenated samarium-iron-nitrogen alloy powder was milled as follows.

(Milling)

One gram of dehydrogenated samarium-iron-nitrogen alloy powder, 20 ml hexane, 100 g of a 1.5 mm diameter zirconia ball was put in a 100 ml plastic container, and then milled at 20 Hz for 5 hours using a vibrating mill apparatus, and thus a magnet powder was obtained.

### Examples 24-1

A magnet powder was obtained in the same manner as Example 24 except that the dehydrogenated samarium-iron-nitrogen alloy powder was milled as follows.

(Disintegration)

One gram of dehydrogenated samarium-iron-nitrogen alloy powder, 20 ml hexane, 100 g of 1.5 mm diameter zirconia balls were put in a 100 ml plastic container, and then milled at 20 Hz for 1 hour using a vibrating mill apparatus, and thus a magnet powder was obtained.

### Examples 25-1

A magnet powder was obtained in the same manner as Example 25 except that the dehydrogenated samarium-iron-nitrogen alloy powder was milled as follows.

(Milling)

One gram of dehydrogenated samarium-iron-nitrogen alloy powder, 20 ml of hexane, 100 g of 1.5 mm diameter zirconia balls were put in a 100 ml plastic container, and then milled at 20 Hz for 1 hour using a vibrating mill apparatus, and thus a magnet powder was obtained.

Next, the presence or absence of single-crystal particles of TbCu₇ type samarium-iron-nitrogen alloy, an intensity ratio of X-ray diffraction peak, a lattice constant ratio, an integral width of X-ray diffraction peak, coercivity, the presence or absence of anisotropy of bonded magnet, anisotropy, a squareness ratio, and residual magnetization were evaluated.

### Presence or Absence of Anisotropy, Degree of Anisotropy, Squareness Ratio, Residual Magnetization of Bonded Magnet

The magnet powder was mixed with the thermoplastic resin and then oriented in a 20 kOe magnetic field, thereby producing a bonded magnet.

Under the conditions at the temperature of 27 degrees C. and the maximum applied magnetic field of 90 kOe created by using the vibration sample type magnetometer VSM, when the residual magnetization in installing the bonded magnet in the orientation direction is denoted Mr_EASY, and when the residual magnetization in installing the bonded magnet in the direction perpendicular to the orientation direction is denoted Mr_HARD, the degree of anisotropy [%] was determined by the following equation.

(1−Mr_HARD/Mr_EASY)×100

Here, when the degree of anisotropy exceeds 1.0%, it was determined that there was anisotropy of the bonded magnet, and when the degree of anisotropy is 1.0% or less, it was determined that there was no anisotropy of the bonded magnet.

In addition, when a bonded magnet is installed in the orientation direction, and when the magnetization where a magnetic field of 90 kOe is applied is denoted M 90 kOe, the squareness ratio was obtained by the following formula.

Mr_EASY/M 90kOe

TABLE 3 shows the evaluation results of the presence or absence of single-crystal particles of TbCu₇ type samarium-iron-nitrogen alloy, an intensity ratio of X-ray diffraction peak, a lattice constant ratio, an integral width of X-ray diffraction peak, coercivity, the presence or absence of anisotropy of bonded magnet, a degree of anisotropy, a squareness ratio, and residual magnetization.

TABLE 3

| | | | | PRESENCE OR | | | |
|---|---|---|---|---|---|---|---|
| | | | | ABSENCE OF | | | INTEGRAL |
| | | MILLING | | SINGLE CRYSTAL | INTENSITY | | WIDTH OF |
| | | DIAMETER | | PARTICLE OF | RATIO OF | | X-RAY |
| | NITRIDING | OF ZrO₂ | MILLING | TbCu₇ TYPE | X-RAY | LATTICE | DIFFRACTION |
| | TEMPERATURE | BALL | TIME | Sm—Fe—N | DIFFRACTION | CONSTANT | PEAK |
| | [° C.] | [mm] | [h] | ALLOY | PEAK | RATIO | [°] |
| EXAMPLE 21 | 320 | — | — | PRESENCE | 0.289 | 0.838 | 0.34 |
| EXAMPLE 21-1 | 270 | — | — | PRESENCE | 0.289 | 0.838 | 0.34 |
| EXAMPLE 21-2 | 370 | — | — | PRESENCE | 0.289 | 0.838 | 0.34 |
| EXAMPLE 21-3 | 420 | — | — | PRESENCE | 0.289 | 0.838 | 0.34 |
| EXAMPLE 21-4 | 320 | 0.5 | 1 | PRESENCE | 0.289 | 0.838 | 0.35 |
| EXAMPLE 21-5 | 320 | 1.0 | 1 | PRESENCE | 0.289 | 0.838 | 0.34 |
| EXAMPLE 21-6 | 320 | 1.5 | 1 | PRESENCE | 0.289 | 0.838 | 0.49 |
| EXAMPLE 21-7 | 320 | 1.5 | 3 | PRESENCE | 0.289 | 0.838 | 0.55 |
| EXAMPLE 21-8 | 320 | 1.5 | 5 | PRESENCE | 0.289 | 0.838 | 0.63 |
| COMPARATIVE | — | — | — | ABSENCE | — | — | — |
| EXAMPLE 21-1 | | | | | | | |
| COMPARATIVE | 420 | — | — | ABSENCE | <0.001 | 0.845 | 0.29 |
| EXAMPLE 5 | | | | | | | |
| COMPARATIVE | 420 | 1.5 | 5 | ABSENCE | <0.001 | 0.845 | 0.88 |
| EXAMPLE 5-1 | | | | | | | |
| EXAMPLE 24 | 320 | — | — | PRESENCE | <0.001 | 0.845 | 0.45 |
| EXAMPLE 24-1 | 320 | 1.5 | 1 | PRESENCE | <0.001 | 0.845 | 0.48 |
| EXAMPLE 25 | 320 | — | — | PRESENCE | 0.060 | 0.842 | 0.26 |
| EXAMPLE 25-1 | 320 | 1.5 | 1 | PRESENCE | 0.060 | 0.842 | 0.30 |

| | | BONDED MAGNET | | | |
|---|---|---|---|---|---|
| | | | | | RESIDUAL |
| | | PRESENCE OR | DEGREE OF | | MAGNETIZATION |
| | COERCIVITY | ABSENCE OF | ANISOTROPY | SQUARENESS | (Mr_EASY) |
| | [kOe] | ANISOTROPY | [%] | RATIO | [emu/g] |
| EXAMPLE 21 | 7.6 | PRESENCE | 12.3 | 0.55 | 78.0 |
| EXAMPLE 21-1 | 3.0 | PRESENCE | 5.7 | 0.45 | 67.6 |
| EXAMPLE 21-2 | 5.0 | PRESENCE | 10.7 | 0.54 | 77.0 |
| EXAMPLE 21-3 | 4.0 | PRESENCE | 8.3 | 0.53 | 75.9 |
| EXAMPLE 21-4 | 8.1 | PRESENCE | 24.2 | 0.60 | 83.2 |
| EXAMPLE 21-5 | 8.8 | PRESENCE | 27.0 | 0.65 | 88.4 |
| EXAMPLE 21-6 | 9.6 | PRESENCE | 32.4 | 0.69 | 92.6 |
| EXAMPLE 21-7 | 8.7 | PRESENCE | 32.0 | 0.69 | 92.6 |
| EXAMPLE 21-8 | 8.0 | PRESENCE | 32.9 | 0.70 | 93.6 |
| COMPARATIVE | 1.0 | — | — | — | — |
| EXAMPLE 21-1 | | | | | |
| COMPARATIVE | 7.5 | ABSENCE | <1 | 0.60 | 71.8 |
| EXAMPLE 5 | | | | | |
| COMPARATIVE | 1.3 | ABSENCE | <1 | 0.47 | 56.2 |
| EXAMPLE 5-1 | | | | | |
| EXAMPLE 24 | 7.2 | PRESENCE | 15.3 | 0.60 | 80.9 |
| EXAMPLE 24-1 | 9.0 | PRESENCE | 35.2 | 0.73 | 98.7 |
| EXAMPLE 25 | 7.5 | PRESENCE | 13.1 | 0.58 | 78.9 |
| EXAMPLE 25-1 | 8.5 | PRESENCE | 31.1 | 0.71 | 96.0 |

From Table 3, it can be seen that the magnet powders of Examples 21-1 to 21-8, 24-1 and 25-1 are anisotropic magnet powders containing single-crystal particles of a TbCu₇ type samarium-iron-nitrogen alloy. Also, it can be seen that the bonded magnets produced using the magnetic powders of Examples 21-1 to 21-8, 24-1, and 25-1 have anisotropy.

In contrast, in Comparative Examples 21-1, a samarium-iron alloy powder having a low coercivity is prepared because the samarium-iron alloy powder is not nitrided.

Because the magnetic powders in Comparative Examples 5 and 5-1 were produced using a quench band of samarium-iron alloy, it is found that the magnetic powder does not contain single-crystal particles of TbCu₇ type samarium-iron-nitrogen alloy. In addition, it can be seen that the bonded magnet produced by using the magnet powder of Comparative Example 5 has no anisotropy.

Next, the presence or absence of anisotropy, a degree of anisotropy, a squareness ratio, residual magnetization, and coercivity of the sintered magnet were evaluated.

### Presence of Absence of Anisotropy, Degree of Anisotropy, Squareness Ratio, Residual Magnetization, Coercivity of Sintered Magnet

In a glove box, a 5.5 mm long, 5.5 mm wide carbide rectangular mold (die) was filled with 0.5 g of magnetic powder of Example 25-1, and then oriented in a 20 kOe magnetic field. The die was then placed in a discharge plasma sintering device with a pressurization mechanism by a servo press machine without exposure to air. Next, the magnet powder was electrically charged and sintered for 1 minute at a pressure of 1200 MPa and a temperature of 500 degrees C. under the condition that the inside of the sintering device was maintained at a vacuum (a pressure of 2 Pa or less and an oxygen concentration of 0.4 ppm or less), thereby producing a sintered magnet. Here, after the magnet powder was electrostatically sintered, the pressure was returned to the atmosphere with an inert gas, and the sintered magnet was taken out into the atmosphere after the temperature fell below 60 degrees C.

Under the conditions at the temperature of 27 degrees C. and the maximum applied magnetic field of 90 kOe created by using the vibration sample type magnetometer VSM, when the residual magnetization in installing the bonded magnet in the orientation direction is made Mr_EASY, and when the residual magnetization in installing the bonded magnet in the direction perpendicular to the orientation direction is made Mr_HARD, the degree of anisotropy [%] was determined by the following equation.

(1−Mr_HARD/Mr_EASY)×100

Here, when the degree of anisotropy exceeds 1%, it was determined that there was anisotropy of the sintered magnet, and when the degree of anisotropy is 1% or less, it was determined that there was no anisotropy of the sintered magnet.

In addition, a sintered magnet is installed in the orientation direction, and when the magnetization in applying a magnetic field of 90 kOe is made M 90 kOe, a squareness ratio was obtained by using the following formula.

Mr_EASY/M_ 90 kOe

A bonded magnet was installed in the orientation direction using a vibration sample magnetometer VSM under conditions at a temperature of 27 degrees C. and in a maximum applied magnetic field of 90 kOe, and the coercivity was measured.

The results showed that the sintered magnet had anisotropy with an anisotropy of 18%. The sintered magnet had a squareness ratio of 0.53, a residual magnetization of 500 emu/cm³, and a coercivity of 6.7 kOe.

Next, an intensity ratio of the (002) plane X-ray diffraction peak to the (110) plane X-ray diffraction peak of the TbCu₇ type samarium-iron-nitrogen alloy phase of the crystal orientation plane (hereinafter referred to as the intensity ratio of the X-ray diffraction peak of the crystal orientation plane), an intensity ratio of the (024) X-ray diffraction peak of the Th₂Zn₁₇ type samarium-iron-nitrogen alloy phase to the (110) plane X-ray diffraction peak of the TbCu₇ type samarium-nitrogen alloy phase of the amorphous orientation plane (hereinafter referred to as the intensity ratio of the X-ray diffraction peak of the amorphous orientation plane), and a lattice constant ratio c/a of a lattice constant c to the lattice constant a of the TbCu₇ type samarium-iron-nitrogen alloy phase of the crystal orientation plane (hereinafter referred to as the lattice constant ratio of the crystal orientation plane), and an integrated width of the (101) X-ray diffraction peak of the TbCu₇ type samarium-iron-nitrogen alloy phase of the crystal orientation plane (hereinafter referred to as an integral width of an X-ray diffraction peak of the crystal orientation plane) were evaluated.

### Intensity Ratio of X-Ray Diffraction Peak of Crystal Orientation Plane, Intensity Ratio of X-Ray Diffraction Peak of Amorphous Orientation Plane, Lattice Constant Ratio of Crystal Orientation Plane, and Integral Width of X-Ray Diffraction Peak of Crystal Orientation Plane

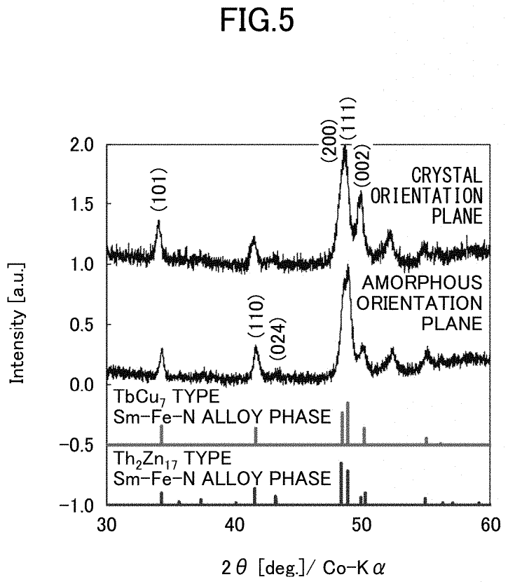

The X-ray diffraction spectra of sintered magnets were measured using an X-ray diffractometer, Empyrean (Malvern Panalytical) and an X-ray detector, Pixcel 1D (Malvern Panalytical). Specifically, the X-ray diffraction spectrum of the sintered magnet was measured using a Co-tube as an X-ray source under the conditions of a tube voltage of 45 kV, a tube current of 40 mA, a measurement angle of 30 to 60 degrees, a measurement step width of 0.013 degrees, and a width scan speed of 0.09 degrees/sec (see FIG. 5).

Peak searching and profile fitting were performed using High Score Plus (Malvern Panalytical) as the X-ray diffraction pattern analysis software, while setting the minimum significance to 1.00.

Specifically, the X-ray diffraction spectrum of the plane perpendicular to the magnetic field application direction obtained by cutting the sintered magnet, i.e., the crystal orientation plane, was measured, and the intensity ratio of the X-ray diffraction peak of the crystal orientation plane was calculated after the integral intensity of the diffraction peak of the (110) plane of the TbCu₇ type samarium-iron-nitrogen alloy phase near 41.5 degrees was obtained, and the integral intensity of the diffraction peak of the (002) plane near 50.1 degrees was obtained.

From FIG. 5, it was found that the intensity ratio of the X-ray diffraction peak at the crystal orientation surface of the sintered magnet is 2.970.

When the (002) plane x-ray diffraction peak overlaps the (200) and (111) plane x-ray diffraction peaks, the ratio of the sum of (002) plane, (200) plane and (111) plane x-ray diffraction peak intensities to the (110) plane x-ray diffraction peak intensity is calculated after calculating the integral intensity of the (200) plane diffraction peak near 48.4 degrees and the (111) plane diffraction peak near 48.9 degrees.

From FIG. 5, it was found that the ratio of the sum of the intensities of the (002) plane, the (200) plane, and the (111) plane X-ray diffraction peaks to the (110) plane X-ray diffraction peak on the crystal orientation surface of the sintered magnet is 9.535.

In addition, the X-ray diffraction spectrum of the surface perpendicular to the crystal orientation surface obtained by cutting the sintered magnet, i.e., the amorphous orientation surface, was measured, and the integral intensity of the (110) plane diffraction peak of the TbCu₇ type samarium-iron-nitrogen alloy phase near 41.5 degrees was obtained, and the integral intensity of the (024) plane diffraction peak of the Th₂Zn₁₇ type samarium-iron alloy phase near 43.2 degrees was obtained, and then the intensity ratio of the X-ray diffraction peak of the amorphous orientation surface was calculated.

From FIG. 5, it was found that the intensity ratio of the X-ray diffraction peak of the amorphous orientation surface of the sintered magnet is 0.001 or less.

Furthermore, after measuring the X-ray diffraction spectrum of the crystal orientation surface of the sintered magnet (see FIG. 5), the lattice constant ratio of the crystal orientation plane was obtained by performing Rietvelt analysis.

From FIG. 5, it was found that the lattice constant ratio of the crystal orientation plane of the sintered magnet was 0.842.

After measuring the X-ray diffraction spectrum of the crystal orientation plane of the sintered magnet (see FIG. 5), the integral width of the (101) plane diffraction peak near 34.3 degrees was obtained.

From FIG. 5, it was found that the integral width of the X-ray diffraction peak of the crystal orientation plane of the sintered magnet was 0.41 degrees.

This application claims priority to Priority Application No. 2019-044954, filed March 12, 2019 with the Japan Patent Office, the contents of which are hereby incorporated by reference in their entirety.

1. An anisotropic magnet powder, comprising:
single-crystal particles of a TbCu₇ type samarium-iron-nitrogen based alloy.

2. The anisotropic magnet powder as claimed in claim 1, wherein an intensity ratio of a (024) plane X-ray diffraction peak of a Th₂Zn₁₇ type samarium-iron-nitrogen based alloy phase to a (110) plane X-ray diffraction peak of the TbCu₇ type samarium-iron-nitrogen based alloy phase is 0.300 or less.

3. The anisotropic magnet powder of claim 1, wherein a ratio c/a of a lattice constant c to a lattice constant a of a TbCu₇ type samarium-iron-nitrogen based alloy phase is 0.838 or more.

4. The anisotropic magnet powder as claimed in claim 1, wherein an integral width of a (101) plane X-ray diffraction peak of a TbCu₇ type samarium-iron-nitrogen based alloy phase is 0.66 degrees or less.

5. The anisotropic magnet powder as claimed in claim 1, wherein a coercivity is 3.0 kOe or more.

6. An anisotropic magnet, comprising:
a TbCu₇ type samarium-iron-nitrogen based alloy.

7. The anisotropic magnet as claimed in claim 6, wherein the anisotropic magnet is a sintered magnet.

8. The anisotropic magnet as claimed in claim 7, wherein an intensity ratio of a (002) plane X-ray diffraction peak to a (110) plane X-ray diffraction peak of a TbCu₇ type samarium-iron-nitrogen based alloy phase of a crystallographic orientation plane exceeds 2.115.

9. The anisotropic magnet as claimed in claim 7, wherein an intensity ratio of a (024) plane X-ray diffraction peak of a TbCu₇ type samarium-iron-nitrogen based alloy phase of an amorphous orientation plane to a (110) plane X-ray diffraction peak of a Th₂Zr₁₇ type samarium-iron-nitrogen based alloy phase is 0.300 or less.

10. The anisotropic magnet as claimed in claim 7, wherein a ratio c/a of a lattice constant c to a lattice constant a of the TbCu₇ type samarium-iron-nitrogen based alloy phase is 0.838 or more.

11. The anisotropic magnet as claimed in claim 7, wherein an integral width of a (101) plane X-ray diffraction peak of a TbCu₇ type samarium-iron-nitrogen based alloy phase of a crystal orientation plane is 0.66 degrees or less.

12. The anisotropic magnet as claimed in claim 7, wherein a coercivity is 3.0 kOe or more.

13. The anisotropic magnet as claimed in claim 7, wherein a crystal grain size is 3.0 μm or less.

14. A method for manufacturing an anisotropic magnet powder, comprising steps of:
producing a samarium-iron based alloy powder by heat treating a composition containing samarium, iron and an alkali metal halide and/or an alkaline earth metal halide at a temperature of a melting point of the alkali metal halide and/or the alkaline earth metal halide or higher; and
producing a samarium-iron-nitrogen based alloy powder by nitriding the samarium-iron based alloy powder,
wherein the temperature for the heat treating is 500 degrees C. or higher and 800 degrees C. or less.

15. The method for manufacturing the anisotropic magnet powder as claimed in claim 14, wherein a concentration of samarium in the alkali metal halide and/or the alkaline earth metal halide at the temperature for heat treating is 3.2 mol/L or more and 8.2 mol/L or less.

16. The method for manufacturing an anisotropic magnet powder as claimed in claim 14,
wherein the the composition further contains a samarium oxide and/or a samarium halide, an iron oxide and/or an iron halide, and an alkali metal and/or an alkaline earth metal.

17. The method for manufacturing the anisotropic magnet powder as claimed in claim 16, wherein the samarium, the samarium oxide and/or the samarium halide are samarium.

18. The method for manufacturing the anisotropic magnet powder as claimed in claim 16, wherein a concentration of the samarium in the alkali metal halide and/or the alkaline earth metal halide at the temperature for heat treating is 3.2 mol/L or more and 8.2 mol/L or less.
